(19) United States
(12) Patent Application Publication
(10) Pub. No.: US 2022/0066625 A1
(43) Pub. Date: Mar. 3, 2022

(54) PROCESSING APPARATUS

(71) Applicant: DISCO CORPORATION, Tokyo (JP)

(72) Inventor: Hidekazu NAKAYAMA, Tokyo (JP)

(21) Appl. No.: 17/406,318

(22) Filed: Aug. 19, 2021

(30) Foreign Application Priority Data
Sep. 1, 2020 (JP) 2020-146709

(51) Int. Cl. G06F 3/0484; G06F 3/0481; G05B 19/418

(52) U.S. Cl. CPC G06F 3/04842; G06F 3/04817; G05B 2219/35488; G06F 3/04847; G05B 2219/32128; G05B 19/41865

(57) ABSTRACT

A control unit of a processing apparatus displays on a display part a selection screen including a screen list, a selection button capable of selecting a first operation screen from the screen list, and an output button for outputting the first operation screen from the screen list as a second operation screen to an external storage device. When an external storage device that has stored a second operation screen on a processing apparatus of the same type as the processing apparatus is connected to a connector, the control unit displays on the display part the second operation screen from the external storage device without going through first operation screens established in a predetermined order.

### BACKGROUND OF THE INVENTION

### Field of the Invention

The present invention relates to a processing apparatus.

### Description of the Related Art

A Processing apparatus accepts operating actions entered by an operator through a plurality of operation screens to let the operator enter processing conditions for the processing apparatus. JP 2009-260251A, for example, discloses a substrate processing system in which, when the login information of the user is entered from a main display device, a main operation screen for the user is displayed on the main display device, and when the login information of the user is entered from an external operating device, an external parameter setting screen for setting an authority parameter of a group to which the user belongs or an external operation screen for the group to which the user belongs is displayed on an external display device.

### SUMMARY OF THE INVENTION

In a case where a processing apparatus has a plurality of operation screens, the operator is required to take an operating action for switching to one of the operation screens for entering processing conditions. Consequently, it has been desired to increase the operability of the processing apparatus for the operator.

It is therefore an object of the present invention to provide a processing apparatus that can increase its operability for the operator in a case where the processing apparatus is capable of switchingly displaying a plurality of operation screens.

In accordance with an aspect of the present invention, there is provided a processing apparatus including a holding table for holding a workpiece thereon, a processing unit for processing the workpiece held on the holding table, a display part for displaying a first operation screen for operating the processing unit, a control unit for controlling the display part to display a plurality of the first operation screens switchingly in a predetermined order, and a connector to which an external storage device is detachably connected, in which the control unit controls the display part to display a selection screen including a screen list representing a list of a plurality of the first operation screens, a selection button for selecting an optional first operation screen from the screen list, and an output button for outputting the first operation screen selected from the screen list as a second operation screen to the external storage device, and controls the display part to display the second operation screen from the external storage device without going through the first operation screens established in the predetermined order when the external storage device that has stored the second operation screen from the processing apparatus or a processing apparatus of the same kind as the processing apparatus is connected to the connector.

Preferably, the control unit controls the display part to display a layout map screen capable of establishing a positional relationship of a plurality of the second operation screens stored in the external storage device, and switches the positional relationship of the second operation screens depending on a changing operating action on the layout map screen.

Preferably, the first operation screen and the second operation screen each have a plurality of operation buttons, and the control unit controls the display part to display a layout changing screen for changing positions of the operation buttons in the second operation screen, and controls the display part to display the operation buttons in the second operation screen on the basis of established coordinates in the layout changing screen.

The processing apparatus according to the present invention is advantageous in that it can increase its operability for the operator in the case where the processing apparatus is capable of switchingly displaying a plurality of operation screens.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view illustrating a structural example of a processing apparatus according to an embodiment of the present invention;

FIG. 2 is a diagram schematically illustrating an example of the functional make-up of the processing apparatus according to the embodiment;

FIG. 3 is a diagram illustrating an example of a screen transition of the processing apparatus according to the embodiment;

FIG. 4 is a diagram illustrating another example of a screen transition of the processing apparatus according to the embodiment;

FIG. 5 is a diagram illustrating an example of a layout map screen of the processing apparatus according to the embodiment;

FIG. 6 is a diagram illustrating an example of a layout changing screen of the processing apparatus according to the embodiment;

FIG. 7 is a flowchart illustrating an example of a processing sequence of a display control process of the processing apparatus according to the embodiment;

FIG. 8 is a flowchart illustrating an example of a processing sequence of the display control process for a selection screen illustrated in FIG. 7;

FIG. 9 is a flowchart illustrating an example of a processing sequence of the display control process for a second operation screen illustrated in FIG. 7; and

FIG. 10 is a diagram illustrating an example of the display control process of the processing apparatus according to the embodiment.

### DETAILED DESCRIPTION OF THE PREFERRED EMBODIMENTS

A preferred embodiment of the present invention will be described in detail hereinbelow with reference to the accompanying drawings. The present invention is not limited to the details of the embodiment described below. The components described below cover those which could easily be anticipated by those skilled in the art and those which are essentially identical to those described above. Furthermore, the arrangements described below can be combined in appropriate manners. Various omissions, replacements, or changes of the arrangements may be made without departing from the scope of the present invention. In the embodiments to be described below, those components that are identical to each other are denoted by identical reference characters, and will be omitted from description.

In the description to be described below, an XYZ orthogonal coordinate system is established and the positional relationship of components will be described with reference to the XYZ orthogonal coordinate system. Directions lying within horizontal planes and extending along the X-axis of the XYZ orthogonal coordinate system will be referred to as X-axis directions, directions lying within the horizontal planes and extending along the Y-axis of the XYZ orthogonal coordinate system perpendicularly to the X-axis directions will be referred to as Y-axis directions, and directions lying within vertical planes and extending along the Z-axis of the XYZ orthogonal coordinate system perpendicularly to the X-axis directions and the Y-axis directions will be referred to as Z-axis directions. An XY plane including the X-axis and Y-axis extends parallel to the horizontal planes, and the Z-axis directions extend vertically perpendicularly to the XY plane.

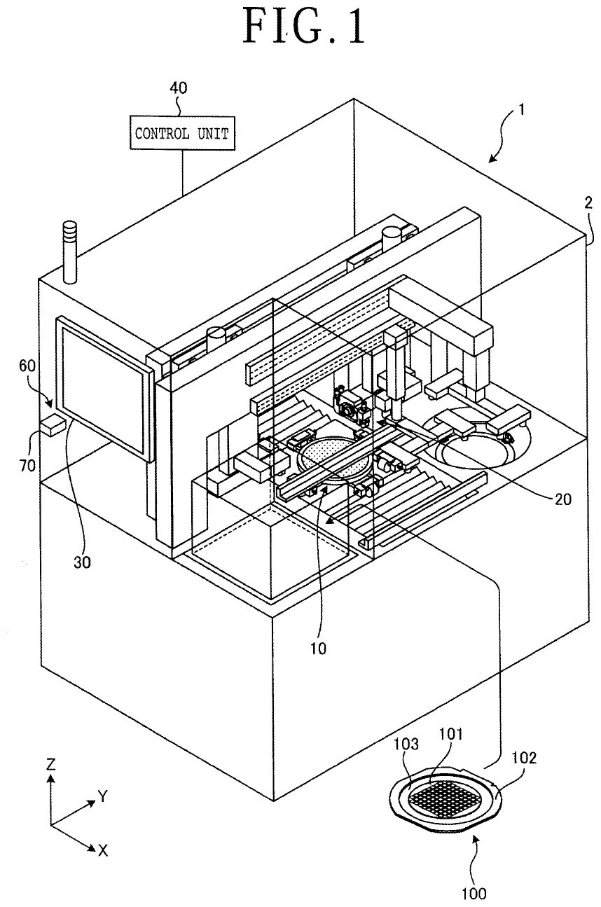

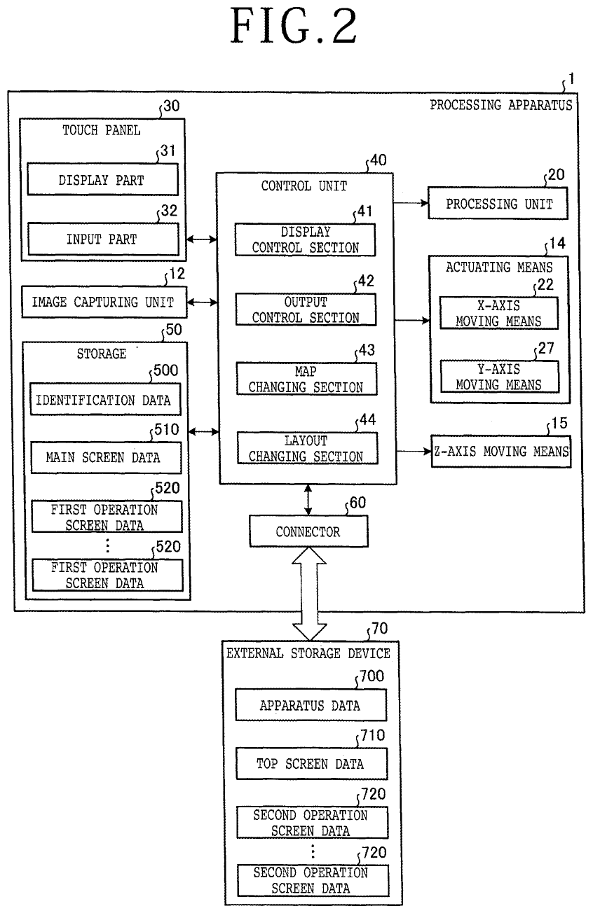

A processing apparatus 1 according to the present embodiment will be described below with reference to FIGS. 1 and 2. FIG. 1 illustrates in perspective a structural example of the processing apparatus 1 according to the present embodiment. FIG. 2 schematically illustrates an example of the functional make-up of the processing apparatus 1 according to the present embodiment.

As illustrated in FIG. 1, the processing apparatus 1 has a main body 2 in the form of a box-shaped housing. As illustrated in FIG. 1, the processing apparatus 1 includes a chuck table 10, a processing unit 20, a touch panel 30, a control unit 40, and a connector 60. The control unit 40 is electrically connected to the chuck table 10, the processing unit 20, the touch panel 30, and the connector 60.

A workpiece 100 as an object to be processed by the processing apparatus 1 includes a semiconductor wafer or an optical device wafer in the shape of a circular plate having a substrate 101 made of silicon, sapphire, gallium arsenide, or the like, for example. The workpiece 100 is disposed in the opening of an annular frame 102 and supported on the annular frame 102 by an adhesive tape 103 affixed to the substrate 101.

The chuck table 10 has a holding surface that holds the workpiece 100 thereon. The chuck table 10 is held in fluid communication with a suction source, not illustrated. The chuck table 10 holds the workpiece 100 under suction on the holding surface by a negative pressure supplied from the suction source. The chuck table 10 is movable in the X-axis directions by X-axis moving means 22 to be described later, and is also rotatable about an axis parallel to the Z-axis by a rotary actuator, not illustrated.

According to the present embodiment, as illustrated in FIG. 2, the processing apparatus 1 further includes an image capturing unit 12, actuating means 14, and Z-axis moving means 15. The control unit 40 is electrically connected to the image capturing unit 12, the actuating means 14, and the Z-axis moving means 15.

As illustrated in FIGS. 1 and 2, the image capturing unit 12 includes an electron microscope incorporating an image sensor such as a charge-coupled device (CCD) or a complementary metal oxide semiconductor (CMOS) sensor. The image capturing unit 12 captures an image of the surface of the workpiece 100 held on the holding surface of the chuck table 10. The image capturing unit 12 is integrally combined with the processing unit 20 by being mounted and supported on a portion of a housing of the processing unit 20. The image capturing unit 12 is movable along the Z-axis directions by the Z-axis moving means 15 that includes a ball screw, a nut, a stepping motor, etc. The image capturing unit 12 may include a light source for applying illuminating light to the surface of the workpiece 100 held on the holding surface of the chuck table 10, for example.

The processing unit 20 processes the workpiece 100 held on the holding surface of the chuck table 10. The processing unit 20 includes a cutting unit including a pair of cutting means, for example, each having a cutting blade. The cutting blades of the respective cutting means face each other along the Y-axis directions and are rotatable about respective axes parallel to the Y-axis. The processing unit 20 cuts the workpiece 100 with the rotating cutting blades. The processing unit 20 is movable along the Y-axis directions by Y-axis moving means 27 and is also movable along the Z-axis directions by the Z-axis moving means 15. The Y-axis moving means 27 that moves the image capturing unit 12 and the processing unit 20 relatively along the Y-axis directions with respect to the holding surface of the chuck table 10 includes a ball screw, a nut, a stepping motor, etc. The X-axis moving means 22 and the Y-axis moving means 27 jointly make up the actuating means 14.

The processing apparatus 1 processes the workpiece 100 held on the holding surface of the chuck table 10 by moving the chuck table 10 and the processing unit 20 relatively to each other with the X-axis moving means 22, the Y-axis moving means 27, and the Z-axis moving means 15.

The processing unit 20 of the processing apparatus 1 is not limited to the cutting unit that cuts the workpiece 100 with the cutting blades. The processing unit 20 may alternatively be a grinding unit for grinding a similar workpiece 100 with grindstones or the like, a polishing unit for polishing a similar workpiece 100 with a polishing pad or the like, or a laser processing unit for applying a laser beam to a similar workpiece 100 to process the workpiece 100.

As illustrated in FIG. 1, the touch panel 30 is mounted on the main body 2 with its display surface facing outwardly. The touch panel 30 is disposed in a location on the main body 2 where it can easily be seen and operated by the operator. The touch panel 30 is controlled by the control unit 40 to display images of the surface of the workpiece 100 captured by the image capturing unit 12 and also various items of information required for processing the workpiece 100, and also to accept operating actions entered by the operator as required for processing the workpiece 100. According to the present embodiment, the touch panel 30 represents an example of a display part.

As illustrated in FIG. 2, the touch panel 30 has a display part 31 for displaying various items of information relative to the processing apparatus 1 and an input part 32 for accepting various operating actions entered by the operator relative to the processing apparatus 1, such as settings of processing conditions. The display part 31 has a display device such as a liquid crystal display or an organic electroluminescent (EL) display, for example. The input part 32 has a touch screen for indicating positions contacted by objects and coordinates on a display surface of the display device, for example.

According to the present embodiment, the touch panel 30 will be described below as an example of an output part for outputting information. However, the touch panel 30 is not limited to such an example. The output part may be implemented as a speaker or an electronic device such as a communication device, for example.

As illustrated in FIG. 2, the processing apparatus 1 includes a storage 50. The storage 50 stores programs for performing functions such as various processes carried out by the control unit 40 and data for use in the processes according to the programs. The storage 50 is electrically connected to the control unit 40. The storage 50 can be implemented by a hard disk drive (HDD), a semiconductor memory, or the like. The storage 50 may also be used as a temporary working area at the time when a processor of the control unit 40 executes instructions described in control programs.

According to the present embodiment, the processing apparatus 1 including the storage 50 will be described below. However, the processing apparatus 1 is not limited to such a detail. The storage 50 may be replaced with an external storage device accessible by the processing apparatus 1, such as an external computer, an external electronic device, or another processing apparatus, for example.

The storage 50 can store various data including identification data 500, main screen data 510, a plurality of pieces of first operation screen data 520, etc., for example. The identification data 500 include data capable of identifying the processing apparatus 1, data capable of identifying working environments of the processing apparatus 1, etc., for example. The main screen data 510 include data in the hypertext markup language (HTML) format for displaying a main screen, for example. The main screen is a higher-level screen to which a plurality of first operation screens are linked, for example.

The first operation screen data 520 correspond to a plurality of processing steps, maintenance, etc. in the processing apparatus 1, and include data in the HTML format for displaying first operation screens through which the operator operates the processing apparatus 1. The first operation screens are configured such that they will be displayed switchingly in a predetermined order when operation buttons on the main screen, other first operation screens, etc. are selected. Switching in the predetermined order means switching to a screen linked to a screen being displayed, switching in the order of numbers assigned respectively to a plurality of screens, or the like, for example. The first operation screens can include screens classified in a hierarchy, e.g., first operation screens in a second layer that are displayed when operation buttons on the main screen are selected, and first operation screens in a third layer that are displayed when operation buttons on the first operation screen in the second layer are selected. In a case where processes, commands, etc. are assigned to the operation buttons on the first operation screens, for example, the first operation screen data 520 include data of such processes, commands, etc. Keyword data capable of identifying operation contents are added to the first operation screen data 520. In a case where images are displayed on the first operation screens, image data representing those images are linked to the first operation screen data 520.

The connector 60 has terminals to which other devices can be connected. For example, the connector 60 may have general-purpose terminals such universal serial bus (USB) terminals. According to the present embodiment, an external storage device 70, for example, can detachably be connected to the connector 60. In the example illustrated in FIG. 1, the connector 60 is disposed on the main body 2 near the touch panel 30 so that the external storage device 70 can detachably be connected to the connector 60 from outside of the main body 2. The connector 60 may send data to and receive data from storage devices, storage mediums of electronic devices, etc. via a cable or wireless communications, for example.

The control unit 40 controls various mechanisms, including the X-axis moving means 22, the Y-axis moving means 27, and the Z-axis moving means 15, for actuating the processing apparatus 1. The control unit 40 controls the components of the processing apparatus 1 to perform a processing process on the workpiece 100. Specifically, the control unit 40 controls the components of the processing apparatus 1 that include the chuck table 10 and the processing unit 20 according to processing conditions set and entered by the operator, for example, thereby performing a processing process on the workpiece 100.

The control unit 40 includes an arithmetic processing device such as a central processing unit (CPU), a storage device such as a read only memory (ROM) or a random access memory (RAM), and an input/output interface device. The control unit 40 thus includes a computer that executes control programs, using the arithmetic processing device, the storage device, and the input/output interface device, to control the components, described above, of the processing apparatus 1 according to a series of processing steps carried out by the processing apparatus 1.

The control unit 40 controls overall operation of the processing apparatus 1 according to processing conditions set by the operator through the input part 32 of the touch panel 30. The control unit 40 controls the touch panel 30 to display operation screens and controls operation of the processing unit 20 depending on operating actions on the operation buttons on the operation screens.

The control unit 40 includes a display control section 41, an output control section 42, a map changing section 43, and a layout changing section 44. The control unit 40 realizes functions, operation, etc. of those sections by executing programs.

The display control section 41 controls the touch panel 30 to display a plurality of first operation screens switchingly in a predetermined order. The display control section 41 controls the touch panel 30 to display a selection screen including a screen list that represents a list of the first operation screens, selection buttons capable of selecting any desired one of the first operation screens from the screen list, and an output button for outputting the first operation screen selected on the selection screen as a second operation screen to the external storage device 70. The display control section 41 controls the touch panel 30 to display a first operation screen on the basis of HTML tags included in the data in the HTML format of the first operation screen data 520. The display control section 41 controls the touch panel 30 to display a second operation screen on the basis of HTML tags included in the data in the HTML format of second operation screen data 720. In other words, the control unit 40 has the functions of a browser for displaying a main screen, a top screen, operation screens, etc.

The display control section 41 controls the touch panel 30 to display a layout map screen capable of establishing a positional relationship of a plurality of the second operation screens stored in the external storage device 70. The display control section 41 controls the touch panel 30 to switch the positional relationship of the second operation screens depending on an operating action to change the layout map screen. The display control section 41 controls the touch panel 30 to display a layout changing screen for changing the positions of the operation buttons on the operation screens. The display control section 41 controls the touch panel 30 to display the operation buttons on the basis of established coordinates in the layout changing screen.

The output control section 42 edits the first operation screen data 520 of a first operation screen selected from the screen list by the operator, as second operation screen data 720. The output control section 42 generates apparatus data 700, top screen data 710, etc. for managing the edited second operation screen data 720. The apparatus data 700 include discriminating data for discriminating a processing apparatus 1 to which the second operation screen data 720 are applicable. The discriminating fata include identification data for identifying the processing apparatus 1, a processing system, etc., apparatus type data, etc. The top screen data 710 include data in the HTML format for displaying the top screen. In a case where the external storage device 70 stores a plurality of second operation screen data 720, for example, the top screen acts as a screen for displaying the thumbnails of second operation screens represented by the plurality of second operation screen data 720 on the basis of an order, a layout map, etc. stored in the external storage device 70. The top screen acts a screen for selectively displaying one of the thumbnails. The top screen acts as a higher-level screen to which a plurality of second operation screens are linked. In a case where the external storage device 70 does not store second operation screen data 720, for example, the top screen acts as a screen for indicating that the external storage device 70 does not store the second operation screens. The output control section 42 outputs the apparatus data 700, the top screen data 710, the second operation screen data 720, etc. to the external storage device 70 connected to the connector 60, thereby storing the various data in the external storage device 70.

The map changing section 43 displays on the touch panel 30 a layout map screen capable of establishing a positional relationship and a display order of the second operation screens represented by the second operation screen data 720 stored in the external storage device 70, etc. The map changing section 43 changes the map, i.e., the positional relationship, of the second operation screens depending on an operating action to change the layout map screen. The map changing section 43 may provide a function to delete the second operation screen data 720. The map changing section 43 changes the positional relationship of the second operation screen data 720 stored in the external storage device 70 into a positional relationship depending on the changing operating action.

The layout changing section 44 changes the layout of the second operation screen represented by the second operation screen data 720 and displayed on the touch panel 30. The layout changing section 44 performs a process for enabling the operator to change the positions of objects such as operation buttons or input fields on the second operation screen represented by the second operation screen data 720 and displayed on the touch panel 30, for example. For example, the layout changing section 44 changes the layout of the second operation screen depending on an operating action such as drag and drop, for example. When the operator instructs that changed contents be saved, the layout changing section 44 changes the second operation screen data 720 based on the changed contents. The layout changing section 44 may be configured to display on the touch panel 30 an input area for entering objects and positional coordinates in the second operation screen as linked to each other and to change the layout of the second operation screen depending on input values applied to the input area. The layout changing section 44 may change the layout of the first operation screen data 520.

The external storage device 70 connected to the connector 60 includes an external storage medium such as a USB memory or a memory card. The external storage device 70 can store various data including the apparatus data 700, the top screen data 710, the second operation screen data 720, etc. output from the processing apparatus 1. The external storage device 70 stores the second operation screen data 720 in the order in which they will be displayed. The external storage device 70 is carried by the operator who operates the processing apparatus 1, for example. The external storage device 70 is connected to the connector 60 when the processing apparatus 1 starts to be used, and is disconnected from the connector 60 when the processing apparatus 1 has finished being used, for example. According to the present embodiment, the external storage device 70 will be described as storing the apparatus data 700, the top screen data 710, the second operation screen data 720. However, the external storage device 70 may store those data as a single batch of data.

The structural example of the processing apparatus 1 according to the present embodiment has been described hereinabove. The structural details described above with reference to FIGS. 1 and 2 are given by way of example only, and the processing apparatus according to the present invention is not limited to the illustrated structural details. The functions and structural details of the processing apparatus 1 according to the present embodiment may flexibly be changed or modified depending on specifications and operational details of the processing apparatus 1.

(Display Examples of Processing Apparatus)

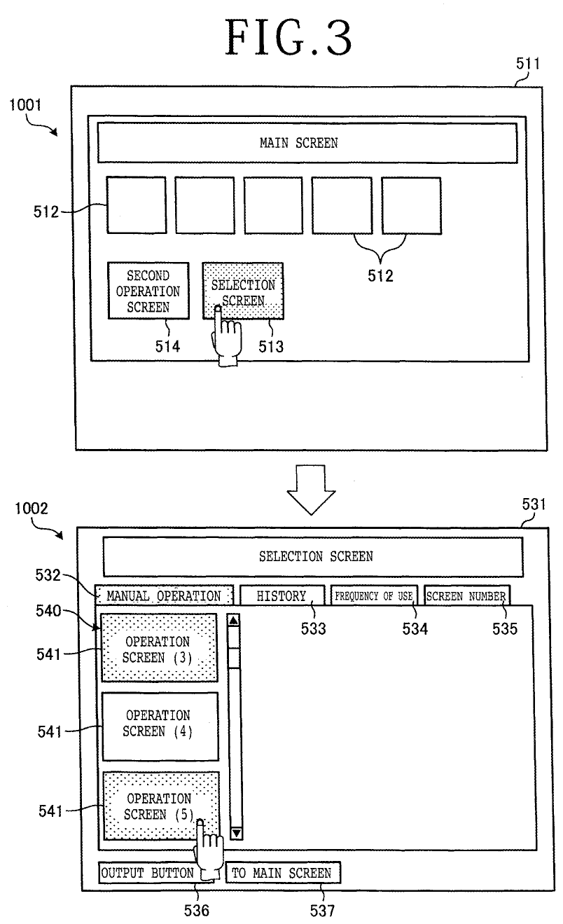

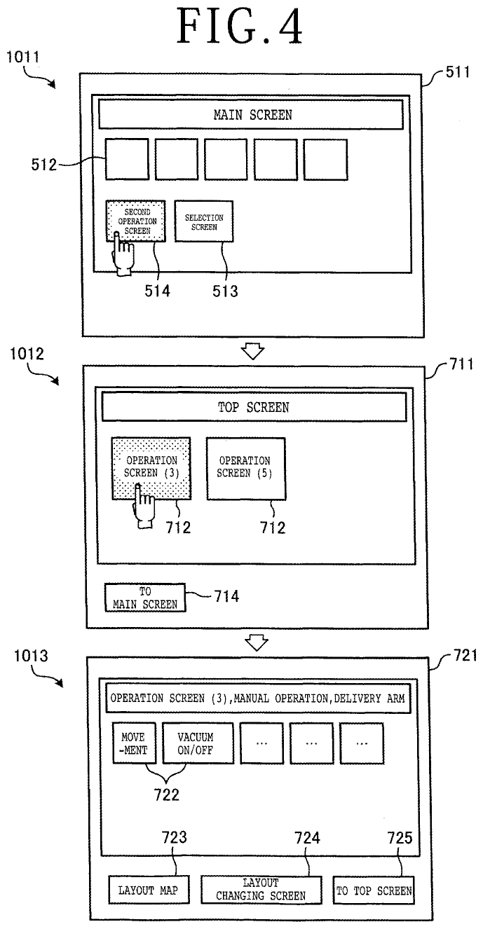

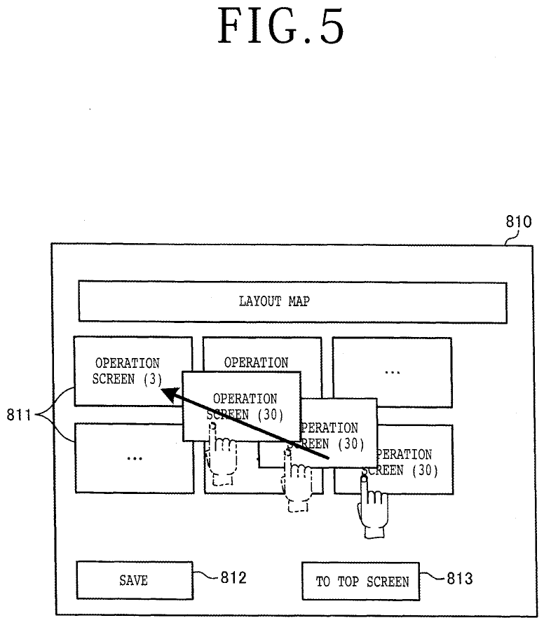

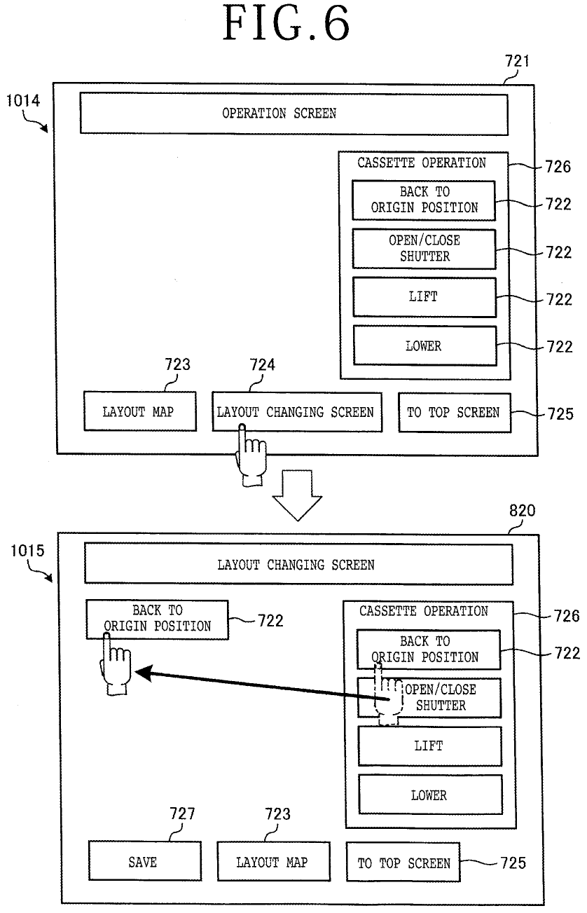

Next, examples of screen transitions carried out by the processing apparatus 1 according to the present embodiment will be described below. FIG. 3 illustrates an example of a screen transition of the processing apparatus 1 according to the present embodiment. FIG. 4 illustrates another example of a screen transition of the processing apparatus 1 according to the present embodiment. FIG. 5 illustrates an example of the layout map screen of the processing apparatus 1 according to the present embodiment. FIG. 6 illustrates an example of the layout changing screen of the processing apparatus 1 according to the present embodiment.

In a scene 1001 illustrated in FIG. 3, the processing apparatus 1 displays a main screen 511 based on main screen data 510 on the touch panel 30. The main screen 511 has icons 512 corresponding respectively to a plurality of first operation screens, a first button 513 capable of selecting a selection screen, and a second button 514 for indicating a transition to a second operation screen. In the example illustrated in the scene 1001, the operator selects the first button 513 in order to display a selection screen. The processing apparatus 1 detects a selecting operating action for the first button 513 through the touch panel 30. The selecting operating action includes, for example, a gesture such as touch, long touch, or flick.

As illustrated in a scene 1002, the processing apparatus 1 generates selection screen data capable of selecting a plurality of pieces of first operation screen data 520 and displays a selection screen 531 based on the selection screen data on the touch panel 30. The selection screen 531 has a button 532, a button 533, a button 534, a button 535, a button 536, and a button 537. The button 532 is a button for instructing the touch panel 30 to display a screen list searched for by manual operation, for example. Manual operation includes, for example, a process in which the operator enters any keyword and searches a plurality of first operation screens for a first operation screen including the keyword. The button 533 is a button for instructing the touch panel 30 to display a screen list based on a history representing the operator, the processing apparatus 1, etc., for example. The screen list based on the history represents, for example, a list of first operation screens arranged in a less recent order of dates and times of use, for example. The button 534 is a button for instructing the touch panel 30 to display a screen list based on the frequency of use, for example. The screen list based on the frequency of use represents, for example, a list of first operation screens arranged in a descending order of frequencies of use. The button 535 is a button for instructing the touch panel 30 to display a screen list based on the screen number. The screen list based on the screen number represents, for example, a list of first operation screens arranged in an order of screen numbers assigned to a plurality of first operation screens. The button 536 is a button for instructing the touch panel 30 to output a plurality of first operation screens selected on a screen list, for example. The button 537 is a button for instructing the touch panel 30 to go back to the main screen 511, for example.

In the example illustrated in the scene 1002, the processing apparatus 1 displays on the selection screen 531 a screen list 540 representing a list of thumbnails 541 of the first operation screens represented by the first operation screen data 520. For example, the processing apparatus 1 displays scrollably on the selection screen 531 a screen list 540 representing a plurality of thumbnails 541 such as an operation screen (3), an operation screen (4), or an operation screen (5). It is assumed, for example, that the operator selects the thumbnails 541 of the operation screen (3) and the operation screen (5), and thereafter selects the button 536 as an output button. In this case, the processing apparatus 1 outputs the first operation screen data 520 respectively representing the operation screen (3) and the operation screen (5) that are selected as second operation screen data 720 to the external storage device 70. The processing apparatus 1 generates apparatus data 700 based on the identification data 500 and outputs the generated apparatus data 700 to the external storage device 70. The processing apparatus 1 generates top screen data 710 of the second operation screen data 720 for displaying the operation screen (3) and the operation screen (5) that are selected, and outputs the generated top screen data 710 to the external storage device 70. The processing apparatus 1 can thus store the apparatus data 700, the top screen data 710, and the second operation screen data 720 in the external storage device 70. In a case where the operator does not continuously operate the processing apparatus 1, the operator disconnects the external storage device 70 that has saved, i.e., stored, the selected second operation screen data 720 therein from the processing apparatus 1, and leaves the place where the processing apparatus 1 is installed.

In a scene 1011 illustrated in FIG. 4, the operator uses the processing apparatus 1 with the external storage device 70 connected to the connector 60. The processing apparatus 1 displays on the touch panel 30 the main screen 511 based on the main screen data 510 and established for the processing apparatus 1. For displaying the second operation screen from the external storage device 70, the operator selects the second button 514. The processing apparatus 1 detects the selecting operating action on the second button 514 through the touch panel 30.

As illustrated in a scene 1012, the processing apparatus 1 displays on the touch panel 30 a top screen 711 based on the top screen data 710 stored in the external storage device 70. As described above, the external storage device 70 stores the second operation screen data 720 corresponding to the operation screen (3) and the operation screen (5). In this case, the processing apparatus 1 displays on the touch panel 30 a top screen 711 having two thumbnails 712 capable of selecting the operation screen (3) and the operation screen (5) that are stored in the external storage device 70. In other words, the processing apparatus 1 can have the operator select the operation screen (3) and the operation screen (5). The top screen 711 has, for example, a button 714 for instructing the touch panel 30 to return to the main screen 511 that has originally been established for the processing apparatus 1. When the button 714 is selected by the operator, the processing apparatus 1 controls the touch panel 30 to switch from the top screen 711 to the main screen 511 and display the main screen 511.

In the scene 1012, the operator selects the thumbnail 712 of the operation screen (3) in order to display the operation screen (3) from the external storage device 70. The processing apparatus 1 detects the selecting operating action on the thumbnail 712 of the operation screen (3) through the touch panel 30.

As illustrated in a scene 1013, the processing apparatus 1 displays on the touch panel 30 an operation screen 721 based on the second operation screen data 720 corresponding to the second operation screen (3) from the external storage device 70. The operation screen 721 represents, for example, an operation screen for a delivery arm of manual operation of the operation screen (3). The operation screen 721 has a plurality of operation buttons 722, a button 723 representing “layout map,” a button 724 representing “layout changing screen,” and a button 725 representing “top screen.” The operation buttons 722 include buttons for instructing the processing apparatus 1 to perform operations including movement, vacuum ON/OFF, etc. The button 723 is a button for instructing the touch panel 30 to display a layout map, for example. The button 724 is a button for instructing the touch panel 30 to display a layout changing screen to be described later, for example. The button 725 is a button for instructing the touch panel 30 to back to the top screen 711.

When the processing apparatus 1 detects an operator's selecting operating action on one of the operation buttons 722, the processing apparatus 1 performs a processing process linked to the selected operation button 722. For example, if the operator selects the operation button 722 representing “movement,” the processing apparatus 1 carries out a control process for moving a delivery arm to deliver a wafer to be cut from a cassette to a loading/unloading area, thereby allowing the operator to control movement of the delivery arm.

When the processing apparatus 1 detects an operator's selecting operating action on the button 723 representing “layout map,” as illustrated in FIG. 5, the processing apparatus 1 displays on the touch panel 30 a layout map screen 810 based on layout map screen data, not illustrated. The layout map screen 810 illustrated in FIG. 5 represents a layout map for changing the layout of the operation screen (3), etc. The layout map screen 810 has, for example, a plurality of icons 811 that act as thumbnails of operation screens and are capable of selecting operation screens, a button 812 representing “save,” and a button 813 representing “to top screen.” In the example illustrated in FIG. 5, the layout map screen 810 displays, as a matrix, the plurality of ions 811 corresponding respectively to an operation screen (3), an operation screen (5), . . . , an operation screen (30) on the basis of the second operation screen data 720 stored in the external storage device 70. The number of the ions displayed by the layout map screen 810 varies depending on the number of the second operation screen data 720 stored in the external storage device 70, the size of the display area of the layout map screen 810, etc. The processing apparatus 1 can accept operator's operating actions for moving the icons 811, switching around the icons 811, etc. The button 812 is a button for reflecting changes in the order and layout of the second operation screen data 720 from the external storage device 70 in the external storage device 70. The button 813 is a button for instructing the touch panel 30 to go back to the top screen 711, for example.

In the example illustrated in FIG. 5, in order to position the operation screen (30) in front of the operation screen (3), the operator drags the icon 811 of the operation screen (30) toward the icon 811 of the operation screen (3), and drops the icon 811 of the operation screen (30) in front of the operation screen (3). When the processing apparatus 1 detects the operator's drag-and-drop action, the processing apparatus 1 moves the icon 811 of the operation screen (30) in front of the operation screen (3), thereby changing the order and layout of the icons 811 of the layout map screen 810.

When the changing of the layout of the icons 811 is finished, the operator selects the button 812 representing “save.” The processing apparatus 1 changes the order and layout of the second operation screen data 720 stored in the external storage device 70 to the changed order and layout of the icons 811 in the layout map screen 810. Since the processing apparatus 1 can thus have the operator change the order and layout of the second operation screen data 720 stored in the external storage device 70, the processing apparatus 1 can be made more convenient to use.

In a scene 1014 illustrated in FIG. 6, the processing apparatus 1 displays on the touch panel 30 an operation screen 721 based on the second operation screen data 720 from the external storage device 70. The operation screen 721 has a plurality of operation buttons 722, a button 723 representing “layout map,” a button 724 representing “layout changing screen,” and a button 725 representing “top screen.” The operation buttons 722 are disposed in an operation area 726 capable of operating the cassette. The operation buttons 722 include, for example, buttons for going back to the origin position, opening/closing a shutter, lifting the cassette, lowering the cassette, etc., for example. The button 723 representing “layout map,” the button 724 representing “layout changing screen,” and the button 725 representing “top screen” are identical to those illustrated in FIG. 4. In the scene 1014, the operator selects the button 724 representing “layout changing screen” in order to change the layout of the operation screen 721.

When the processing apparatus 1 detects an operator's selecting operating action on the button 724 representing “layout changing screen,” the processing apparatus 1 displays on the touch panel 30 a layout changing screen 820 based on layout changing screen data, not illustrated, as indicated by a scene 1015 illustrated in FIG. 6. The layout changing screen 820 is configured such that the operator can move objects including the operation buttons 722, the operation area 726, etc. in order to change the layout of the operation screen 721, for example. The layout changing screen 820 has a button 727 representing “save,” a button 723 representing “layout map,” and a button 725 representing “top screen.” The button 812 representing “save” is a button for instructing the processing apparatus 1 to save changed contents of the layout changing screen 820. In other words, the button 727 is a button for changing the second operation screen data 720 stored in the external storage device 70 so that the layout of the operation screen 721 will incorporate the changed contents. The button 723 is a button for instructing the touch panel 30 to display a layout map, for example. The button 725 is a button for instructing the touch panel 30 to back to the top screen 711.

In the example illustrated in the scene 1015, the operator performs a drag-and-drop operation to move the operation button 722 for “going back to the origin position” out of the operation area 726. When the processing apparatus 1 detects the operator's drag-and-drop operation, the processing apparatus 1 changes the layout of the operation buttons 722 in the operation screen 721 on the basis of the detected operator's drag-and-drop operation.

When the changing of the layout of the operation buttons 722 is finished, the operator selects the button 727 representing “save.” The processing apparatus 1 changes the second operation screen data 720 stored in the external storage device 70 to the changed layout of the layout changing screen 820. For example, the processing apparatus 1 changes the HTML data of the second operation screen data 720 to the layout of the layout changing screen 820. Inasmuch as the processing apparatus 1 can thus change the layout of the second operation screen data 720 stored in the external storage device 70, the processing apparatus 1 can provide the operator with a second operation screen that is different in layout from a first operation screen.

(Example of Display Control of Processing Apparatus)

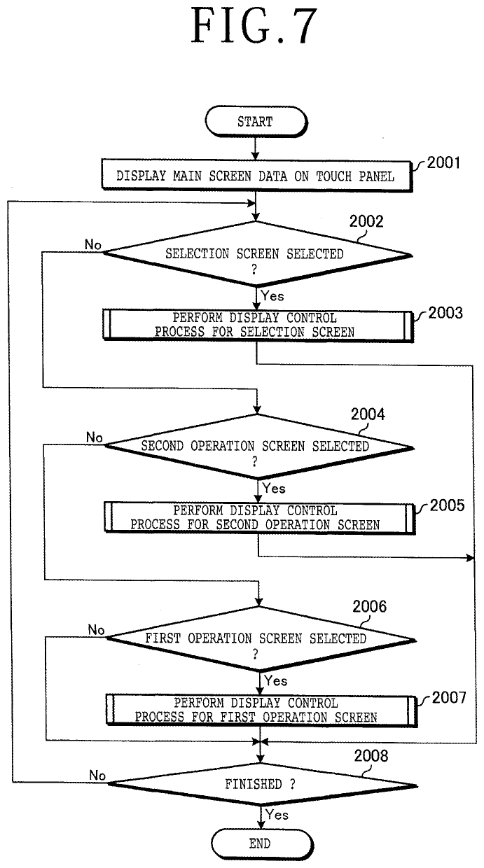

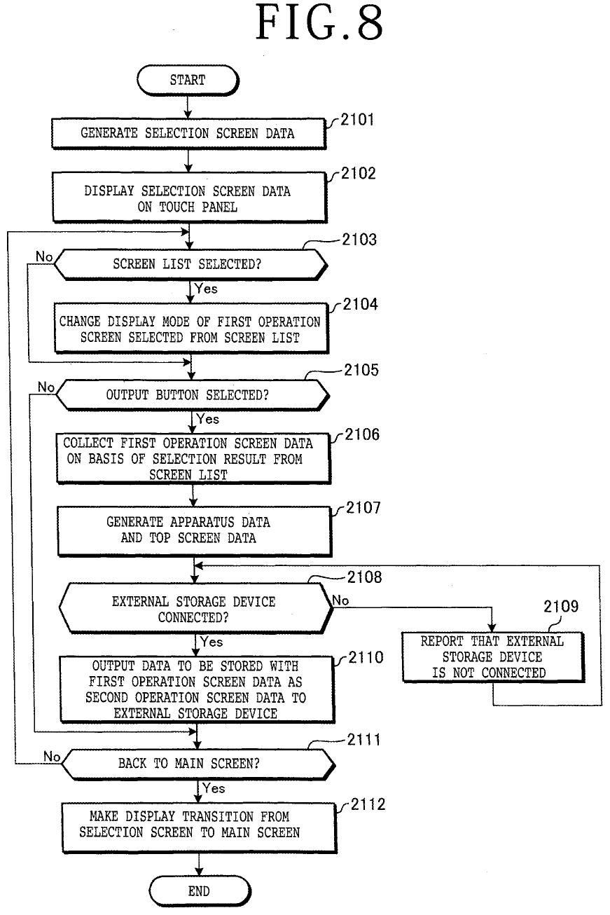

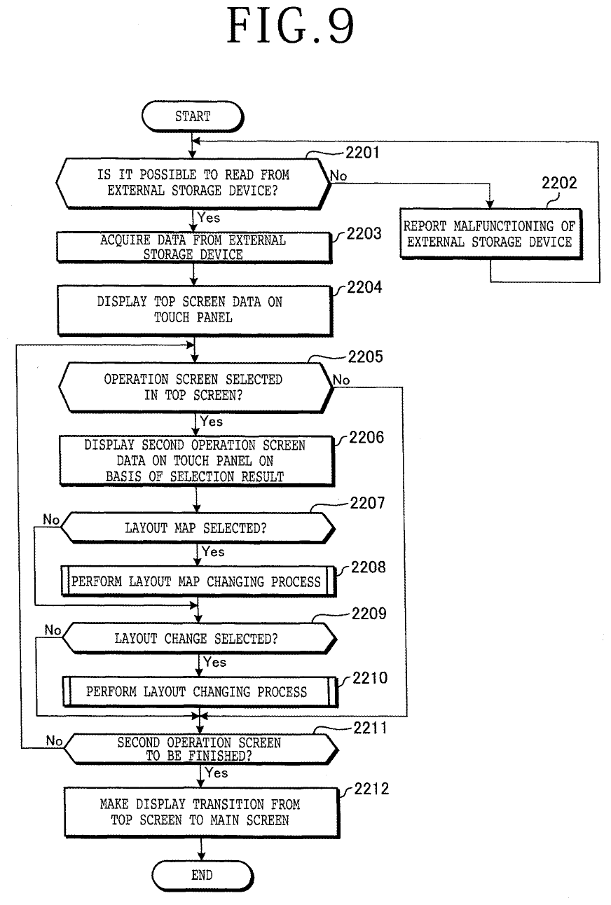

An example of a display control process for operation screens that is carried out by the processing apparatus 1 according to the present embodiment will be described below. FIG. 7 is a flowchart illustrating an example of a processing sequence of the display control process of the processing apparatus 1 according to the embodiment. FIG. 8 is a flowchart illustrating an example of a processing sequence of the display control process for a selection screen illustrated in FIG. 7. FIG. 9 is a flowchart illustrating an example of a processing sequence of the display control process for a second operation screen illustrated in FIG. 7. The processing sequences illustrated in FIGS. 7 through 9 are carried out when the control unit 40 of the processing apparatus 1 executes programs. The processing sequences illustrated in FIGS. 7 through 9 are performed upon activation of the processing apparatus 1, for example.

As illustrated in FIG. 7, the control unit 40 of the processing apparatus 1 displays the main screen data 510 on the touch panel 30 (step 2001). For example, the control unit 40 controls the touch panel 30 to display the main screen 511 represented by the HTML data of the main screen data 510. As a result, the touch panel 30 displays the main screen 511. When the control unit 40 has finished step 2001, the control unit 40 proceeds with its processing sequence to step 2002.

The control unit 40 determines whether the selection screen 531 is selected or not (step 2002). For example, in a case where the control unit 40 detects the selection of the first button 513 representing “selection screen” through the touch panel 30, the control unit 40 determines that the selection screen 531 is selected. If the control unit 40 determines that the selection screen 531 is selected (Yes in step 2002), then the control unit 40 proceeds with its processing sequence to step 2003.

The control unit 40 performs a display control process for the selection screen 531 (step 2003). The display control process for the selection screen 531 realizes a process about the display of the selection screen 531, for example, when the control unit 40 executes programs.

In the example illustrated in FIG. 8, the control unit 40 generates selection screen data (step 2101). For example, the control unit 40 generates selection screen data including HTML data so as to be able to select a plurality of pieces of first operation screen data 520. For example, the control unit 40 generates selection screen data for displaying a selection screen 531 having a screen list 540 of first operation screen data 520, a button 532, a button 533, a button 534, a button 535, a button 536, and a button 537, as described above. When the control unit 40 has finished step 2101, the control unit 40 proceeds with its processing sequence to step 2102.

The control unit 40 displays selection screen data on the touch panel 30 (step 2102). For example, the control unit 40 controls the touch panel 30 to display a selection screen 531 represented by the selection screen data. As a result, the touch panel 30 displays the selection screen 531. When the control unit 40 has finished step 2102, the control unit 40 proceeds with its processing sequence to step 2103.

The control unit 40 determines whether the screen list 540 is selected or not (step 2103). For example, in a case where the control unit 40 detects the selection of the screen list 540 of the selection screen 531 through the touch panel 30, the control unit 40 determines that the screen list 540 is selected. If the control unit 40 determines that the screen list 540 is not selected (No in step 2103), the control unit 40 proceeds with its processing sequence to step 2105 to be described later. If the control unit 40 determines that the screen list 540 is selected (Yes in step 2103), then the control unit 40 proceeds with its processing sequence to step 2104.

The control unit 40 changes the display mode of the first operation screen selected from the screen list 540 (step 2104). For example, the control unit 40 controls the display on the touch panel 30 such that the selected first operation screen and unselected first operation screens have respective display modes distinguishable from each other in the screen list 540. When the control unit 40 has finished step 2104, the control unit 40 proceeds with its processing sequence to step 2105.

The control unit 40 determines whether the output button is selected or not (step 2105). For example, in a case where the control unit 40 detects the selection of the button 536 as “output button” through the touch panel 30, the control unit 40 determines that the output button is selected. If the control unit 40 determines that the output button is not selected (No in step 2105), then the control unit 40 proceeds with its processing sequence to step 2111. If the control unit 40 determines that the output button is selected (Yes in step 2105), then the control unit 40 proceeds with its processing sequence to step 2106.

The control unit 40 collects the first operation screen data 520 on the basis of the selection result from the screen list 540 (step 2106). For example, the control unit 40 collects the first operation screen data 520 selected from the screen list 540 from the storage 50. When the control unit 40 has finished step 2106, the control unit 40 proceeds with its processing sequence to step 2107.

The control unit 40 generates apparatus data 700 and top screen data 710 (step 2107). For example, the control unit 40 generates apparatus data 700 capable of discriminating a processing apparatus 1 that can use an external storage device 70, a processing apparatus 1 that has generated an external storage device 70, etc. on the basis of the identification data 500 stored in the storage 50, etc. For example, the control unit 40 generates top screen data 710 representing a higher-level top screen 711 that links the second operation screen data 720 based on the selected first operation screen data 520. When the control unit 40 has finished step 2107, the control unit 40 proceeds with its processing sequence to step 2108.

The control unit 40 determines whether the external storage device 70 is connected or not (step 2108). For example, in a case where the external storage device 70 is connected to the connector 60, or in a case where the external storage device 70 is accessible, or the like, the control unit 40 determines that the external storage device 70 is connected. If the control unit 40 determines that the external storage device 70 is not connected (No in step 2108), then the control unit 40 proceeds with its processing sequence to step 2109.

The control unit 40 reports that the external storage device 70 is not connected (step 2109). For example, the control unit 40 reports that the external storage device 70 is not connected to the connector 60. For example, the control unit 40 may prompt the operator to connect the external storage device 70 to the connector 60. When the control unit 40 has finished step 2109, the control unit 40 returns its processing sequence to step 2108, waiting for the external storage device 70 to be connected. The processing sequence illustrated in FIG. 8 may be arranged such that when the control unit 40 has finished step 2110, the control unit 40 proceeds with its processing sequence to step 2111.

If the control unit 40 determines that the external storage device 70 is connected (Yes in step 2108), then the control unit 40 proceeds with its processing sequence to step 2110. The control unit 40 outputs data to be stored including first operation screen data 520 as second operation screen data 720 to the external storage device 70 (step 2110). For example, the control unit 40 outputs apparatus data 700, top screen data 710, second operation screen data 720, etc. to the external storage device 70 connected to the connector 60, thereby storing various data in the external storage device 70. The processing apparatus 1 can thus the store apparatus data 700, the top screen data 710, and the second operation screen data 720 in the external storage device 70. When the control unit 40 has finished step 2109, the control unit 40 proceeds with its processing sequence to step 2111.

The control unit 40 determines whether to go back to the main screen 511 or not (step 2111). For example, in a case where the control unit 40 detects the selection of the button 536 representing “to main screen” through the touch panel 30, the control unit 40 determines that it is to go back to the main screen 511. If the control unit 40 determines that it is not to go back to the main screen 511 (No in step 2111), then the control unit 40 returns its processing sequence to step 2103 described above, and continues the processing sequence. If the control unit 40 determines that it is to go back to the main screen 511 (Yes in step 2111), then the control unit 40 proceeds with its processing sequence to step 2112.

The control unit 40 makes a display transition from the selection screen 531 to the main screen 511 (step S2112). For example, the control unit 40 controls the touch panel 30 to erase the displayed selection screen 531 and display the main screen 511. When the control unit 40 has finished step 2112, the control unit 40 finishes the processing sequence illustrated in FIG. 8 and returns to step 2003 of the processing sequence illustrated in FIG. 7. In FIG. 7, when the control unit 40 has finished step 2003, the control unit 40 proceeds with its processing sequence to step 2008 to be described later.

If the control unit 40 determines that the selection screen 531 is not selected (No in step 2002), then the control unit 40 proceeds with its processing sequence to step 2004. The control unit 40 determines whether a second operation screen is selected or not (step 2004). For example, in a case where the control unit 40 detects the selection of the second button 514 for indicating a transition from the main screen 511 to a second operation screen through the touch panel 30, the control unit 40 determines that a second operation screen is selected. If the control unit 40 determines that a second operation screen is selected (Yes in step 2004), then the control unit 40 proceeds with its processing sequence to step 2005.

The control unit 40 performs a display control process for a second operation screen (step 2005). The display control process for a second operation screen realizes a process about the display of the top screen data 710, the second operation screen data 720, etc. stored in the external storage device 70, for example, when the control unit 40 executes programs.

In the example illustrated in FIG. 9, the control unit 40 determines whether it is possible to read from the external storage device 70 or not (step 2201). For example, in a case where it is possible to read data from the external storage device 70 through the connector 60, or in a case where the apparatus data 700 stored in the external storage device 70 are applicable to the processing apparatus 1, or the like, the control unit 40 determines that it is possible to read from the external storage device 70. If the control unit 40 determines that it is not possible to read from the external storage device 70 (No in step 2201), then the control unit 40 proceeds with its processing sequence to step 2202.

The control unit 40 reports the malfunctioning of the external storage device 70 (step 2202). For example, the control unit 40 displays a screen reporting that the external storage device 70 is malfunctioning on the touch panel 30, or turns on an indicator lamp to give a warning. For example, the control unit 40 may report details of the malfunctioning to the operator. When the control unit 40 has finished step 2202, the control unit 40 returns its processing sequence to step 2201, waiting for the external storage device 70 to be connected. The processing sequence illustrated in FIG. 9 may be arranged such that when the control unit 40 has finished step 2202, the control unit 40 proceeds with its processing sequence to step 2211.

If the control unit 40 determines that it is possible to read from the external storage device 70 (Yes in step 2201), then the control unit 40 proceeds with its processing sequence to step 2203. The control unit 40 acquires data from the external storage device 70 (step 2203). For example, the control unit 40 acquires data such as the top screen data 710 or the second operation screen data 720 from the external storage device 70 through the connector 60, and stores the acquired data in the storage 50. When the control unit 40 has finished step 2203, the control unit 40 proceeds with its processing sequence to step 2204.

The control unit 40 displays the top screen data 710 on the touch panel 30 (step 2204). For example, the control unit 40 controls the touch panel 30 to display the top screen 711 represented by the top screen data 710. As a result, the touch panel 30 displays the top screen 711. When the control unit 40 has finished step 2204, the control unit 40 proceeds with its processing sequence to step 2205.

The control unit 40 determines whether the operation screen 721 is selected in the top screen 711 or not (step 2205). For example, in a case where the control unit 40 detects the selection of the thumbnail 712 of the top screen 711 through the touch panel 30, the control unit 40 determines that the operation screen 721 is selected in the top screen 711. If the control unit 40 determines that the operation screen 721 is not selected in the top screen 711 (No in step 2205), then the control unit 40 proceeds with its processing sequence to step 2211. If the control unit 40 determines that the operation screen 721 is selected in the top screen 711 (Yes in step 2205), then the control unit 40 proceeds with its processing sequence to step 2206.

On the basis of the selection result, the control unit 40 displays the second operation screen data 720 on the touch panel 30 (step 2206). For example, the control unit 40 controls the touch panel 30 to display the operation screen 721 represented by the second operation screen data 720. As a result, the touch panel 30 displays the operation screen 721. When the control unit 40 has finished step 2206, the control unit 40 proceeds with its processing sequence to step 2207.

The control unit 40 determines whether the layout map is selected or not (step 2207). For example, in a case where the control unit 40 detects the selection of the button 723 representing “layout map” of the operation screen 721 through the touch panel 30, the control unit 40 determines that the layout map is selected. If the control unit 40 determines that the layout map is not selected (No in step 2207), then the control unit 40 proceeds with its processing sequence to step 2209 to be described later. If the control unit 40 determines that the layout map is selected (Yes in step 2207), then the control unit 40 proceeds with its processing sequence to step 2208.

The control unit 40 performs a layout map changing process (step 2208). The layout map changing process includes, for example, a process of displaying the layout map screen 810 based on the layout map screen data on the touch panel 30, a process of changing the layout of the second operation screen data 720 depending on movement of the icons 811, a process of reflecting layout changes in the external storage device 70, etc. The control unit 40 realizes the operation of the processing apparatus 1 as illustrated in FIG. 5 by performing the layout map changing process. When the control unit 40 has finished step 2208, the control unit 40 proceeds with its processing sequence to step 2209.

The control unit 40 determines whether a layout change is selected or not (step 2209). For example, in a case where the control unit 40 detects the selection of the button 724 representing “layout changing screen” through the touch panel 30, the control unit 40 determines that a layout change is selected. If the control unit 40 determines that a layout change is not selected (No in step 2209), the control unit 40 proceeds with its processing sequence to step 2211. If the control unit 40 determines that a layout change is selected (Yes in step 2209), the control unit 40 proceeds with its processing sequence to step 2210.

The control unit 40 carries out a layout changing process (step 2210). The layout changing process includes, for example, a process of displaying the layout changing screen 820 based on the layout changing screen data on the touch panel 30, a process of changing the layout depending on movement of the displayed operation buttons 722, a process of reflecting the changed layout in the second operation screen data 720 stored in the external storage device 70, etc. The control unit 40 realizes the operation of the processing apparatus 1 as illustrated in FIG. 6 by performing the layout changing process. When the control unit 40 has finished step 2210, the control unit 40 proceeds with its processing sequence to step 2211.

The control unit 40 determines whether the second operation screen is to be finished or not (step 2211). For example, in a case where the control unit 40 is instructed to make a transition to the main screen 511 through the touch panel 30, or in a case where the control process based on the second operation screen is finished, or the like, the control unit 40 determines that the second operation screen is to be finished. If the control unit 40 determines that the second operation screen is not to be finished (No in step 2211), then the control unit 40 returns its processing sequence to step 2205 described above, and continues the processing sequence. If the control unit 40 determines that the second operation screen is to be finished (Yes in step 2211), then the control unit 40 proceeds with its processing sequence to step 2212.

The control unit 40 makes a display transition from the top screen 711 to the main screen 511 (step S2212). For example, the control unit 40 controls the touch panel 30 to erase the displayed top screen 711 and display the main screen 511. When the control unit 40 has finished step 2212, the control unit 40 finishes the processing sequence illustrated in FIG. 9 and returns to step 2005 of the processing sequence illustrated in FIG. 7. In FIG. 7, when the control unit 40 has finished step 2005, the control unit 40 proceeds with its processing sequence to step 2008 to be described later.

If the control unit 40 determines that a second operation screen is not selected (No in step 2004), the control unit 40 proceeds with its processing sequence to step 2006. The control unit 40 determines whether a first operation screen is selected or not (step 2006). For example, in a case where the control unit 40 detects the selection of an icon 512 in the main screen 511 through the touch panel 30, the control unit 40 determines that a first operation screen is selected. If the control unit 40 determines that a first operation screen is not selected (No in step 2006), then the control unit 40 proceeds with its processing sequence to step 2008. If the control unit 40 determines that a first operation screen is selected (Yes in step 2006), then the control unit 40 proceeds with its processing sequence to step 2007.

The control unit 40 performs a display control process for a first operation screen (step 2007). The display control process for a first operation screen realizes a process about the display of the first operation screen data 520 stored in the storage 50, for example, when the control unit 40 executes programs. The display control process for a first operation screen includes, for example, a process of displaying a first operation screen based on the first operation screen data 520 on the touch panel 30, a process of instructing the processing apparatus 1 to be controlled or executing control programs depending on the operation buttons in the operation screens, etc. The control unit 40 controls the display of a first operation screen by performing the display control process for a first operation screen. When the control unit 40 has finished step 2007, the control unit 40 proceeds with its processing sequence to step 2008.

The control unit 40 determines whether the processing sequence of the display control process is to be finished or not (step 2008). For example, in a case where finishing conditions for the processing apparatus 1 are satisfied, the control unit 40 determines that the processing sequence of the display control process is to be finished. The finishing conditions include conditions representing the acceptance of finishing instructions from the operator, an administrative apparatus, other processing apparatus, etc., the finishing of the processing of all workpieces, etc. If the control unit 40 determines that the processing sequence of the display control process is not to be finished (No in step 2008), then the control unit 40 returns its processing sequence to step 2002. If the control unit 40 determines that the processing sequence of the display control process is to be finished (Yes in step 2008), then the processing sequence illustrated in FIG. 7 is ended.

As described above, the processing apparatus 1 can display the selection screen 531 on the touch panel 30 and store first operation screen data 520 selected from the plurality of first operation screen data 520 established in a predetermined order as second operation screen data 720 in the external storage device 70. When the external storage device 70 is connected to the connector 60, the processing apparatus 1 can display the second operation screen data 720 from the external storage device 70 on the touch panel 30 without going through the first operation screen data 520 established in the predetermined order. Accordingly, in a case where the number of first operation screen data 520 that can switchingly be displayed is increased due to an increase in and a diversity of operable functions, the processing apparatus 1 can limit the first operation screen data 520 to only those depending on processing operations and store the limited first operation screen data 520 as second operation screen data 720 in the external storage device 70. As a consequence, the processing apparatus 1 can have the operator choose from the limited second operation screen data 720, resulting in increased work efficiency.

For example, a processing apparatus may store first operation screen data 520 divided in layers as representing an operation screen in a second layer to be displayed on the touch panel the by selecting an operation button 722 in the main screen 511 and an operation screen in a third layer to be displayed on the touch panel 30 by selecting an operation button 722 in the operation screen in the second layer, among a plurality of operation screens, i.e., first operation screens. In this case, though operations on the processing apparatus are limitative, if an operation screen to be operated that is represented by first operation screen data 520 is in a deep layer, then the operator has to go through a display transition across a plurality of first operation screens in order to reach the operation screen in the deep layer, a process that is inefficient.

In contrast, the processing apparatus 1 according to the present embodiment can establish first operation screen data 520 selected from a plurality of pieces of first operation screen data 520 as second operation screen data 720 for the operator to operate with ease. Furthermore, the operator may carry the external storage device 70 that stores the second operation screen data 720 and connect the external storage device 70 to any processing apparatus 1, so that operation screens suitable for the operator can be displayed and operated. As a result, even if the second operation screen data 720 have been stored on a different processing apparatus 1, the processing apparatus 1 has improved operability for the operator by making available an operation screen, i.e., a second operation screen, that is dedicated or limited to the operator.

Furthermore, the processing apparatus 1 can display on the touch panel 30 the layout map screen 810 capable of establishing the positional relationship of a plurality of pieces of second operation screen data 720 stored in the external storage device 70, and switch the positional relationship of the second operation screen data 720 depending on a changing operating action on the layout map screen 810. Therefore, the processing apparatus 1 can store the second operation screen data 720 in a positional relationship different from the positional relationship of the first operation screen data 520. As a result, the processing apparatus 1 can lay out the second operation screen data 720 in an order as favored by the operator, thereby allowing the order of the operation screens to be customized.

Moreover, the processing apparatus 1 can display on the touch panel 30 the layout changing screen 820 for changing the positions of the operation buttons 722 in the second operation screen data 720, and display the operation buttons 722 in the second operation screen data 720 based on established coordinates in the layout changing screen 820. The processing apparatus 1 can thus change the layout of the operation buttons 722 in the second operation screen data 720 stored in the external storage device 70. As a consequence, since the processing apparatus 1 can change the layout of the operation buttons in the first operation screen data 520 and the second operation screen data 720 that represent identical operation screens, the layout of the operation screens can be customized.

Furthermore, the external storage device 70 that stores the apparatus data 700 can be carried by the operator. Therefore, the second operation screen data 720 can be displayed on another processing apparatus compatible with the apparatus data 700, a feature that is highly convenient for the operator.

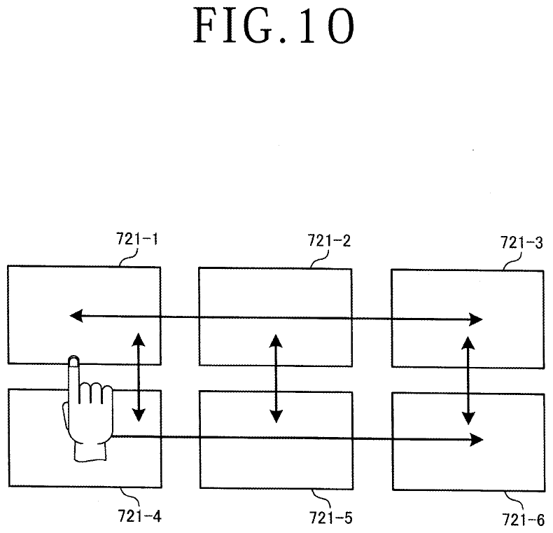

FIG. 10 is a diagram illustrating an example of the display control process of the processing apparatus 1 according to the present embodiment. As illustrated in FIG. 10, the processing apparatus 1 has a function to display switchingly in a predetermined order an operation screen 721-1, an operation screen 721-2, an operation screen 721-3, an operation screen 721-4, an operation screen 721-5, and an operation screen 721-6 on the basis of a plurality of pieces of second operation screen data 720 stored in the external storage device 70. The predetermined order includes an order from the operation screen 721-1 to the operation screen 721-2, the operation screen 721-3, the operation screen 721-4, the operation screen 721-5, and then the operation screen 721-6. The predetermined order also includes an order to switch between the operation screen 721-1 and the operation screen 721-4, an order to switch between the operation screen 721-2 and the operation screen 721-5, and an order to switch between the operation screen 721-3 and the operation screen 721-6. The second operation screen data 720 stored in the external storage device 70 make various switching orders possible by linking link destination information. For example, the processing apparatus 1 displays the operation screen 721-1 on the touch panel 30 and then switches to and displays either one of the operation screen 721-2 and the operation screen 721-4 in a prescribed order depending on the direction in which the operator swipes at the operation screen 721-1.

[Modifications]

According to the above embodiment, the processing apparatus 1 displays the top screen data 710 from the external storage device 70 on the touch panel 30, and displays the second operation screen data 720 selected in the top screen data 710. However, the processing apparatus 1 is not limited to such details. The processing apparatus 1 may be arranged to display on the touch panel 30 the second operation screen data 720 corresponding to the operation screen at the top of the layout map screen 810 at the time when the display of the second operation screen is selected, rather than displaying the top screen data 710 on the touch panel 30, and switch and display the second operation screen data 720 on the touch panel 30 in a predetermined order based on the positional relationship that is established in the layout map depending on the direction of a swipe.

### OTHER EMBODIMENTS

The processing apparatus 1 according to the present invention is not limited to the above embodiment, but various changes and modifications may be made therein without departing from the scope of the invention. For example, the processing apparatus 1 according to the present invention may be a grinding apparatus or a laser processing apparatus rather than a cutting apparatus.

The components of the processing apparatus 1 according to the present embodiment as described above are basically functional and conceptual and may not necessarily be physically constructed as illustrated. Specifically, the components of the processing apparatus 1 are not limited to the discrete and integrated forms as specifically illustrated, but may wholly or partly be functionally or physically discrete and integrated into any units depending on various loads thereon and situations in which they are used. For example, the display control section 41, the output control section 42, the map changing section 43, and the layout changing section 44 of the processing apparatus 1 may be functionally integrated or combined.

Furthermore, the processing apparatus 1 according to the present embodiment has been described as having the operator select first operation screen data 520. However, the present invention is not limited to such details. The processing apparatus 1 may have the administrator select first operation screen data 520 suitable for the type and work contents thereof, and the selected first operation screen data 520 may be stored as second operation screen data 720 in the external storage device 70.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A processing apparatus comprising:
a holding table for holding a workpiece thereon;
a processing unit for processing the workpiece held on the holding table;
a display part for displaying a first operation screen for operating the processing unit;
a control unit for controlling the display part to display a plurality of the first operation screens switchingly in a predetermined order; and
a connector to which an external storage device is detachably connected,
wherein the control unit
controls the display part to display a selection screen including a screen list representing a list of a plurality of the first operation screens, a selection button for selecting an optional first operation screen from the screen list, and an output button for outputting the first operation screen selected from the screen list as a second operation screen to the external storage device, and
controls the display part to display the second operation screen from the external storage device without going through the first operation screens established in the predetermined order when the external storage device that has stored the second operation screen from the processing apparatus or a processing apparatus of a same kind as the processing apparatus is connected to the connector.

2. The processing apparatus according to claim 1,
wherein the control unit
controls the display part to display a layout map screen capable of establishing a positional relationship of a plurality of the second operation screens stored in the external storage device, and
switches the positional relationship of the second operation screens depending on a changing operating action on the layout map screen.

3. The processing apparatus according to claim 1,
wherein the first operation screen and the second operation screen each have a plurality of operation buttons, and
wherein the control unit
controls the display part to display a layout changing screen for changing positions of the operation buttons in the second operation screen, and
controls the display part to display the operation buttons in the second operation screen on a basis of established coordinates in the layout changing screen.
